(19) United States
(12) Patent Application Publication
(10) Pub. No.: US 2014/0217416 A1
(43) Pub. Date: Aug. 7, 2014

(54) NITRIDES BASED SEMICONDUCTOR DEVICE

(71) Applicants: National Central University, Jhongli City (TW); Delta Electronics, Inc., Taoyuan Hsien (TW)

(72) Inventors: Wen-Chia LIAO, Taoyuan Hsien (TW); Yue-Ming HSIN, Jhongli City (TW)

(73) Assignees: National Central University, Jhongli City (TW); Delta Electronics, Inc., Taoyuan Hsien (TW)

(21) Appl. No.: 14/175,494

(22) Filed: Feb. 7, 2014

Related U.S. Application Data
(60) Provisional application No. 61/762,170, filed on Feb. 7, 2013.

(51) Int. Cl. H01L 29/778

(52) U.S. Cl. CPC H01L 29/778
USPC 257/76

(57) ABSTRACT

A nitride-based semiconductor device is disclosed, including a substrate, an active region including a plurality of nitride-based semiconductor layers disposed on the substrate, wherein a 2DEG channel and a two-dimensional hole gas (2DHG) under the two-dimensional electron gas (2DEG) channel are formed within the plurality of nitride-based semiconductor layers, a gate electrode disposed on the top of the active region and an interconnection structure electrically connected with the gate electrode and the 2DHG.

### CROSS REFERENCE TO RELATED APPLICATIONS

This application claims the benefit of U.S. Provisional Application No. 61/762,170 filed Feb. 7, 2013, the entirety of which is incorporated by reference herein.

### BACKGROUND OF THE INVENTION

1. Field of the Invention

The present invention relates to a semiconductor device, and more particularly, to a nitride based semiconductor device.

2. Description of the Related Art

III-Nitride semiconductor devices are well known. In such devices, a 2DEG conductive layer is formed at the boundary surface between two layers, for example, the boundary surface between a bottom GaN layer and a top AlGaN layer. Spaced source and drain electrodes are connected to the AlGaN layer. A gate electrode, which may be an insulated gate or Schottky gate is disposed between the source and drain electrodes. When a gate potential is applied to the gate, the 2DEG layer under the gate is interrupted. Thus, the device is normally conductive and “on” (in the absence of a gate signal) and is turned “off” in response to the gate signal. The device is therefore a normally on switch and is a depletion mode (D-mode) device.

Transconductance performance of III-Nitride devices, however, can be improved. Therefore, it is desirable for III-Nitride devices to improve gate controllability.

### BRIEF SUMMARY OF INVENTION

The invention provides a nitride-based semiconductor device comprising a substrate, an active region comprising a plurality of nitride-based semiconductor layers disposed on the substrate, wherein a two-dimensional electron gas (2DEG) channel and a two-dimensional hole gas (2DHG) under the 2DEG channel are formed within the plurality of nitride-based semiconductor layers, a gate electrode disposed the top of the active region, and an interconnection structure electrically connected with the gate electrode and the 2DHG.

The invention further provides a nitride-based semiconductor device comprising, a substrate, an active region comprising a plurality of nitride-based semiconductor layers disposed on the substrate, wherein a 2DEG channel and a 2DHG under the 2DEG channel are formed within the plurality of nitride-based semiconductor layers, a first gate electrode disposed the top of the active region, and a second gate electrode disposed electrically connected to the 2DHG, wherein the first gate electrode controls the 2DEG channel and the second gate electrode controls the 2DEG channel via the 2DHG.

### BRIEF DESCRIPTION OF DRAWINGS

The invention can be more fully understood by reading the subsequent detailed description and examples with references made to the accompanying drawings, wherein,

FIG. 1A to FIG. 1H show a method for forming a nitride based semiconductor device of an embodiment of the invention.

FIG. 2A shows a plane view of a nitride based semiconductor, device of an embodiment of the invention, wherein FIG. 1H is a cross section along line A-A′ if FIG. 2A.

FIG. 2B shows a plane view of a nitride based semiconductor device of another embodiment of the invention.

FIG. 3 shows a band diagram of the section under gate electrodes of the semiconductor device of FIG. 1 H.

FIG. 4A shows a simulation diagram of a traditional nitride based semiconductor device with only a 2DEG channel.

FIG. 4B shows a band diagram of the FIG. 4A.

FIG. 5A shows a simulation diagram of a nitride based semiconductor device with a 2DEG channel and a 2DHG of an embodiment of the invention.

FIG. 5B shows a band diagram of the FIG. 5A.

FIG. 6A shows a nitride based semiconductor device of a first example of the invention.

FIG. 6B shows a nitride based semiconductor device of a second example of the invention.

FIG. 7 shows a curve diagram of three examples with drain current and transconductance as a function of gate voltage.

### DETAILED DESCRIPTION OF INVENTION

It is understood that specific embodiments are provided as examples to teach the broader inventive concept, and one of ordinary skill in the art can easily apply the teaching of the present disclosure to other methods or apparatus. The following discussion is only used to illustrate the invention, not limit the invention.

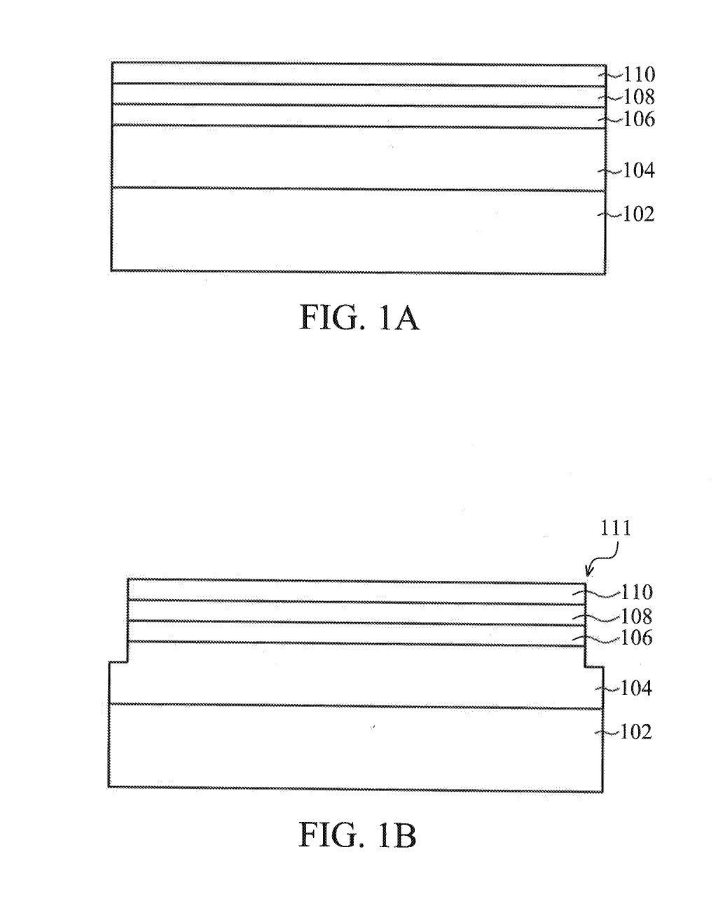

A method for forming a nitride based semiconductor device is illustrated in accordance with FIG. 1A to FIG. 1H. First, referring to FIG. 1A, a substrate 102 is provided. The substrate 102 can be any suitable semiconductor material. For example, the substrate 102 can be Si, SiC, Ge, SiGe, GaAs, InAs, InP, AlN or GaN. Next, a buffer layer 104 is formed on the substrate 102. The buffer layer 104 preferably is a nitride based material to provide good adhesion for the layers thereon and also solve issues of lattice mismatch. In an embodiment of the invention, the buffer layer 104 can be Al_{w}Ga_{1-w}N, wherein w can be 0%˜30%, or a supper lattice stack structure, such as Al_{q}Ga_{1-q}N/GaN, wherein q can be 0˜100%, and a thickness thereof can be 100˜10000 nm. The buffer layer 104 can be formed by metal organic chemical vapor deposition (MOCVD) with suitable process conditions. Thereafter, a first barrier layer 106 is formed on the buffer layer 104. The first barrier layer 106 can be AlₓGa₁₋ₓN or InₓAl₁₋ₓN, wherein x can be 0.15˜1 and a thickness thereof can be 2˜40 nm. A channel layer 108 is formed on the first barrier layer 106. The channel layer 108 can be Al_{y}Ga_{1-y}N, wherein y can be 0˜0.1 and a thickness thereof can be 5˜100 nm. The channel layer 108 can be formed by metal organic chemical vapor deposition (MOCVD) with suitable process conditions. Next, a second barrier layer 110 is formed on the channel layer 108. The second barrier layer 110 can be Al_{z}Ga_{1-z}N or Al_{z}In_{1-z}N, wherein z can be 0.15˜0.35 and a thickness thereof can be 10˜40 nm. The second barrier layer 110 can be formed by metal organic chemical vapor deposition (MOCVD) with suitable process conditions. In an embodiment of the invention, the channel layer 108 has a bandgap smaller than the first barrier layer 106 and the second barrier layer 110.

Referring to FIG. 1B, the first barrier layer 106, the channel layer 108 and the second barrier layer 110 are etched to define a plurality of active regions 111. Next, referring to FIG. 1C, ohmic contacting source electrodes 112 and drain electrodes 114 are formed on the second barrier layer 110. In an embodiment of the invention, a patterned photoresist layer (not shown) with a plurality of openings to define the ohmic contacting source electrodes 112 and drain electrodes 114 is first formed on the second barrier layer 110. A first metal layer, such as a stack of Ti, Al, Ti and Au layers, is then formed thereon and filled into the openings. After that, the ohmic contacting source electrodes 112 and drain electrodes 114 can be formed by stripping the patterned photoresist layer and the first metal layer. In another embodiment, the first metal layer is first formed on the second barrier layer 110 and is then patterned by lithography and etching to form the ohmic contacting source electrodes 112 and drain electrodes 114. Furthermore, a rapid thermal annealing (RTA) process under 700° C.˜950° C. in an N₂ ambiance with a duration of 20 sec˜100 sec can be performed to the first metal layer.

Referring to FIG. 1D, the second barrier layer 110 and the channel layer 108 are etched with an etching process to expose the first barrier layer 106. Next, referring to FIG. 1E, a back gate electrode 116 is formed on the exposed portion of the first barrier layer 106. In an embodiment of the invention, the back gate layer 116 is a stack of Ni and Au layers. Furthermore, a furnace annealing process under 350° C.˜750°C. in an O₂ ambiance can be performed to the back gate electrode 116. Thereafter, referring to FIG. 1F, a passivation layer 118 is formed on the second barrier layer 110, covering the source electrodes 112 and the drain electrodes 114. In an embodiment of the invention, the passivation layer 118 can be SiNₓ, SiOₓ, AlOₓ or HfOₓ. In an embodiment, the passivation layer 118 can be formed by chemical vapor deposition. Referring to FIG. 1G, a lithography process and an etching process is performed to the passivation layer for forming first openings 120 exposing the second barrier layer 110. Thereafter, referring to FIG. 1H, a second metal layer is deposited into the openings to form schottky contacting gate electrodes 122. Next, a further lithography process and an etching process can be performed to the passivation layer 118 to form second openings 124 exposing the back gate electrode 116. Thereafter, an interconnection structure (such as wires, not shown) can be formed to connect the gate electrode 122 and/or the back gate electrode 116 to outer circuits.

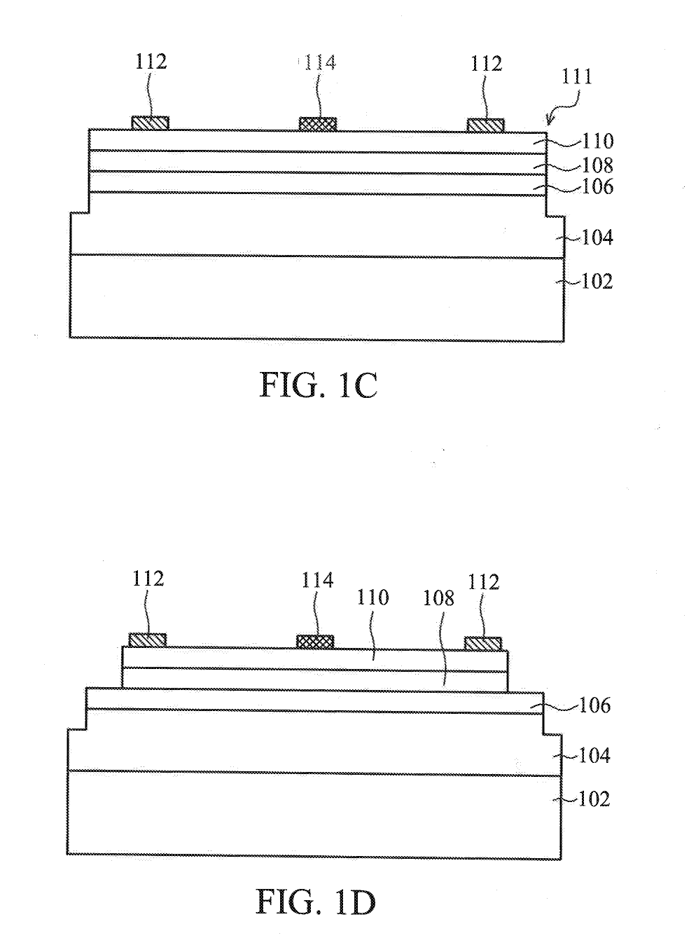

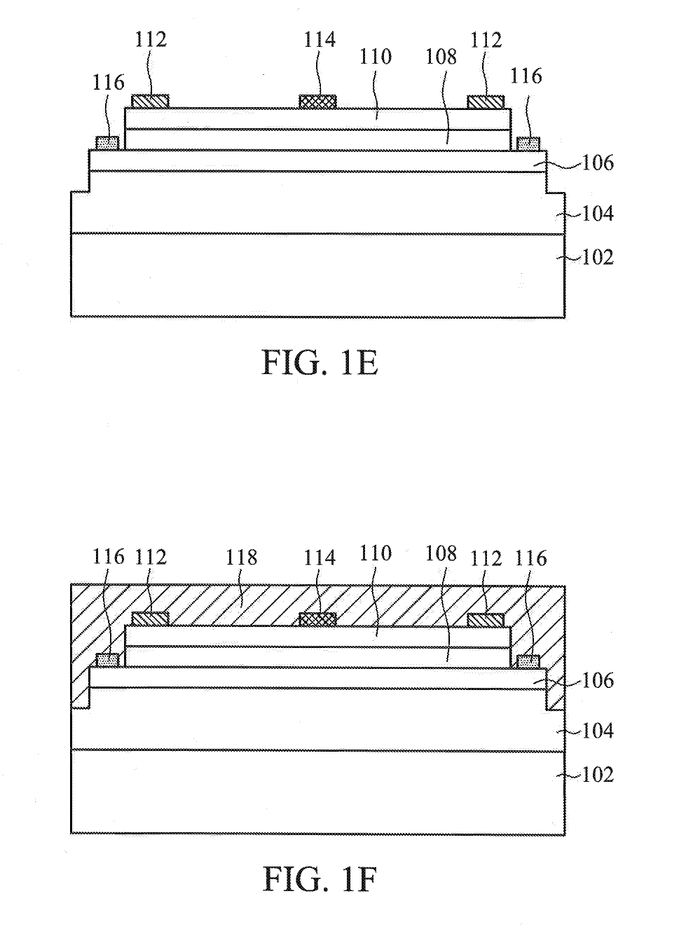

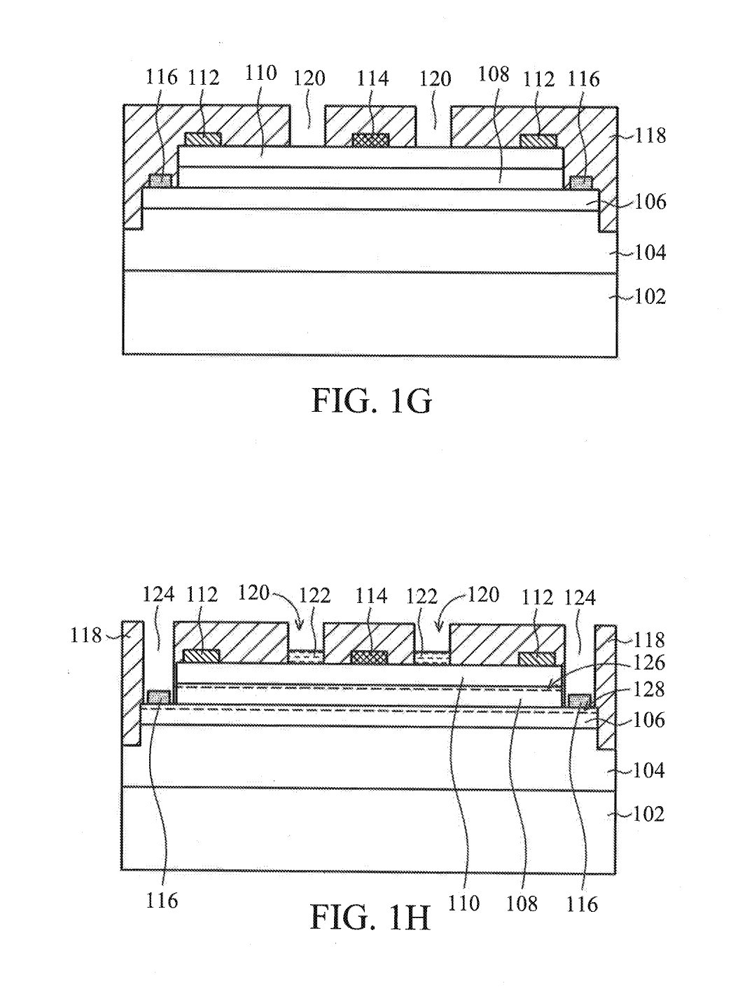

FIG. 2A shows a plane view of the FIG. 1H, wherein FIG. 1H is a cross section along line A-A′ of FIG. 2A. FIG. 3 shows a band diagram of the semiconductor device of FIG. 1 H. Referring to FIG. 1 H, FIG. 2A and FIG. 3, due to the band diagram engineering, a two-dimensional electron gas (2DEG) channel 126 is formed adjacent to a first interface between the second barrier layer 110 and the channel layer 108, and a two-dimensional hole gas (2DHG) 128 is formed adjacent to a second interface between the first barrier layer 106 and the channel layer 108. Referring to FIG. 2A, which shows a plane view of a nitride-based semiconductor device of an embodiment of the invention, the gate electrode 122 and the back gate electrode 116 are connected together. Referring to FIG. 2B, which shows a plane view of a nitride-based semiconductor device of another embodiment of the invention, the gate electrode 122 and the back gate electrode 125 are disconnected and the two gate electrodes 122, 125 can be operated independently.

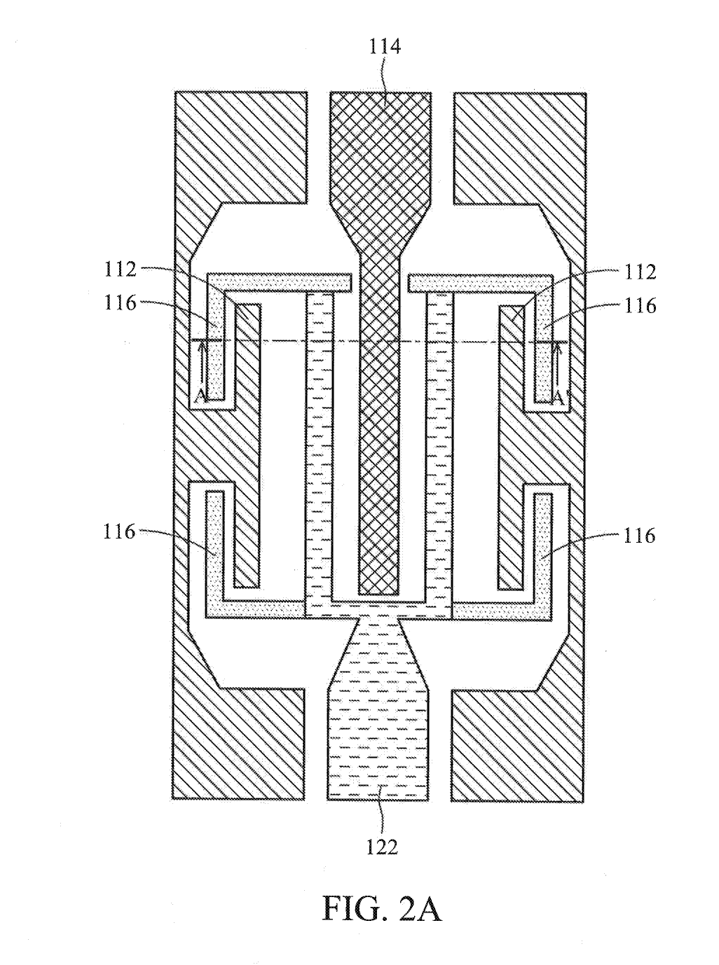

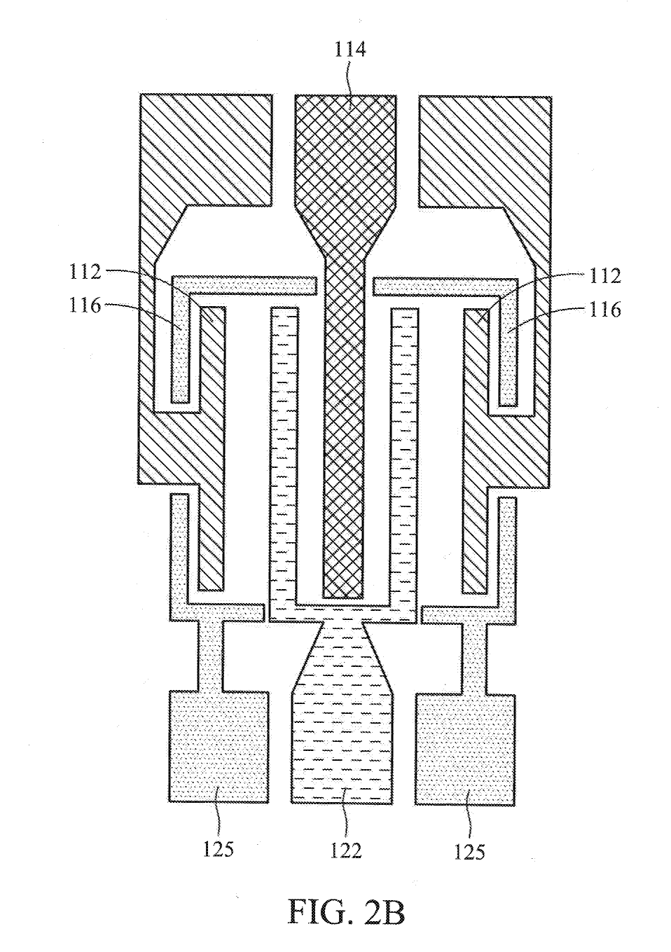

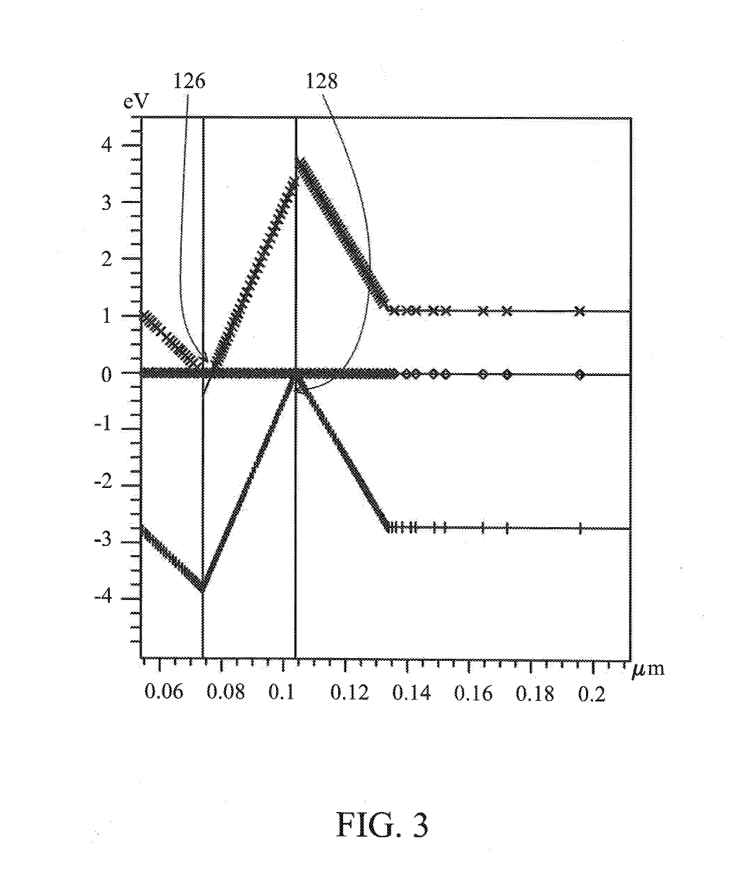

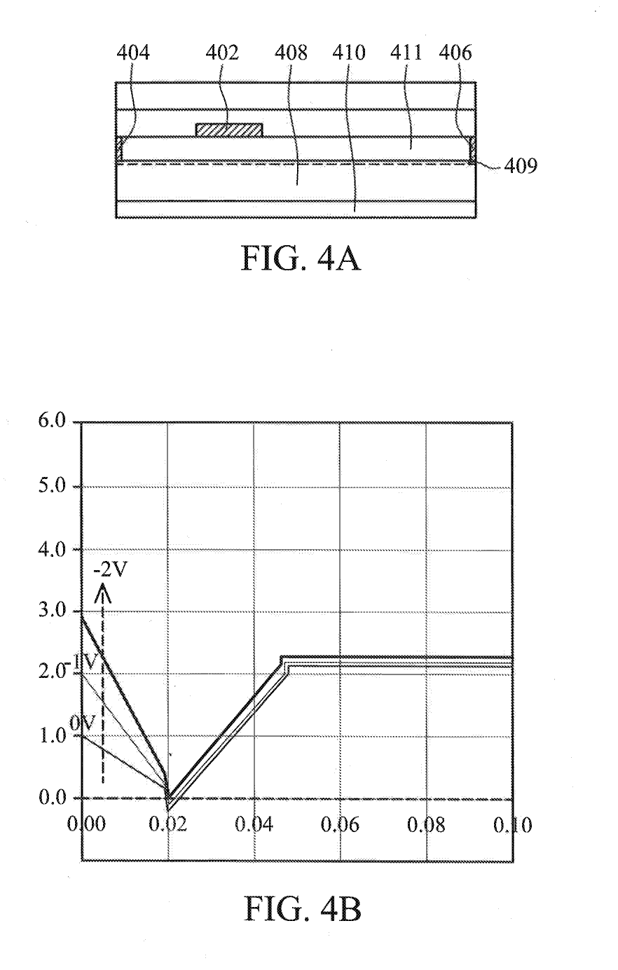

FIG. 4A shows a simulation diagram of a traditional nitride based semiconductor device with only a 2DEG channel. FIG. 4B shows a band diagram of the FIG. 4A. The semiconductor device of FIG. 4A has a buffer layer 410, a channel layer 408, a barrier layer 411 (nitride based semiconductor layer), a 2DEG 409, a source electrode 404 and a drain electrode 406 overlying the channel layer 408, and a gate electrode 402 on the barrier layer 411. FIG 5A shows a simulation diagram of a nitride based semiconductor device with a 2DEG channel and a 2DHG of an embodiment of the invention. The semiconductor device of FIG. 5A has a first barrier layer 518 (nitride based semiconductor layer), a 2DHG 512, a 2DEG channel 516, a channel layer 510, a second barrier layer 508, a source electrode 504 and a drain electrode 506 overlying the second barrier layer 508, a gate electrode 502 on the second barrier layer 508, and a back gate electrode 514 contacting the first barrier layer 518. FIG. 5B shows a band diagram of the 5A. Compared to the traditional nitride based semiconductor device of FIGS. 4A and 4B, the nitride based semiconductor device of 5A and 5B with a 2DEG channel 516 and a 2DHG 518 of an embodiment of the invention can rise the band (for example, the conduction band and the valence band) to a higher slope when applied with a specific negative voltage, such as −1V or −2V, and the 2DHG 512 connected to the outer circuit through the back gate electrode 514 can help to control the 2DEG channel. 516. That is, the 2DEG channel 516 can be controlled both by the gate electrode 502 and the by the 2DHG 512 in accordance with the back gate electrode 514. This phenomenon can help the nitride based semiconductor device to have greater gate controllability.

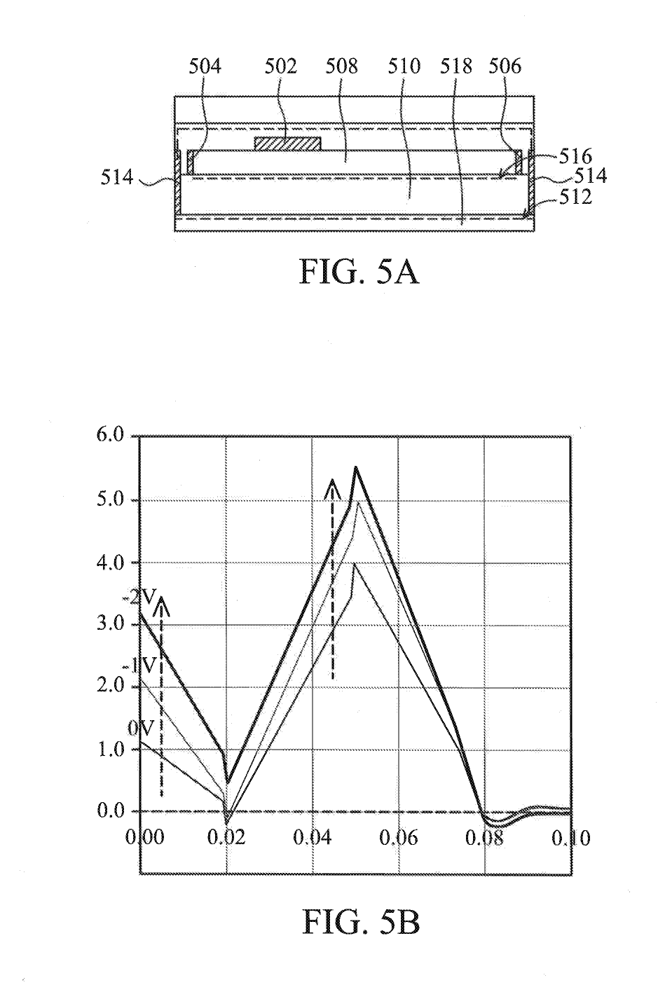

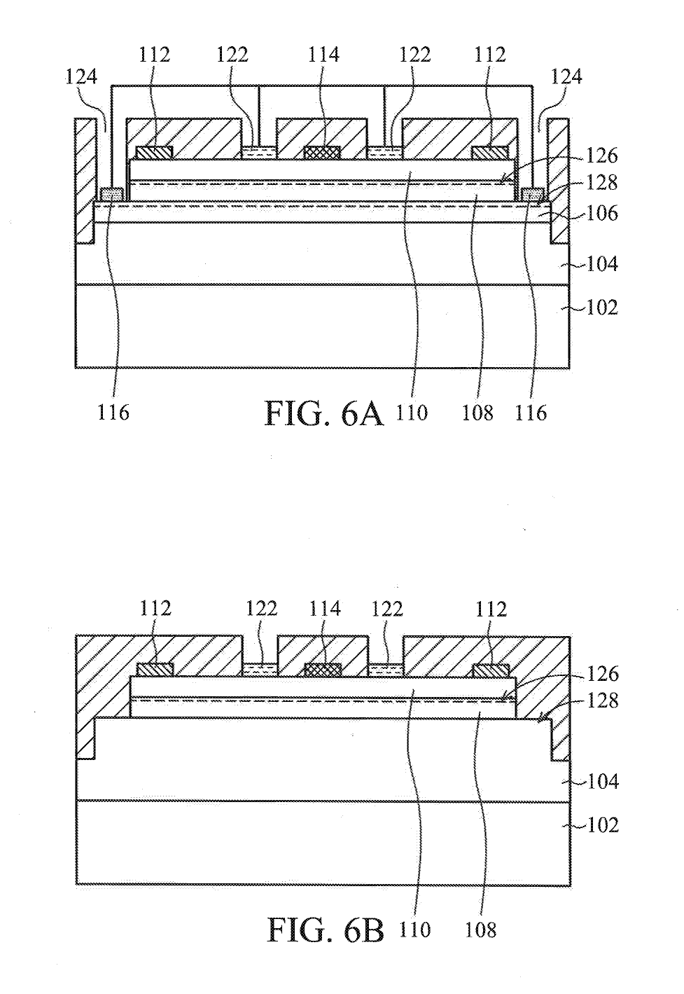

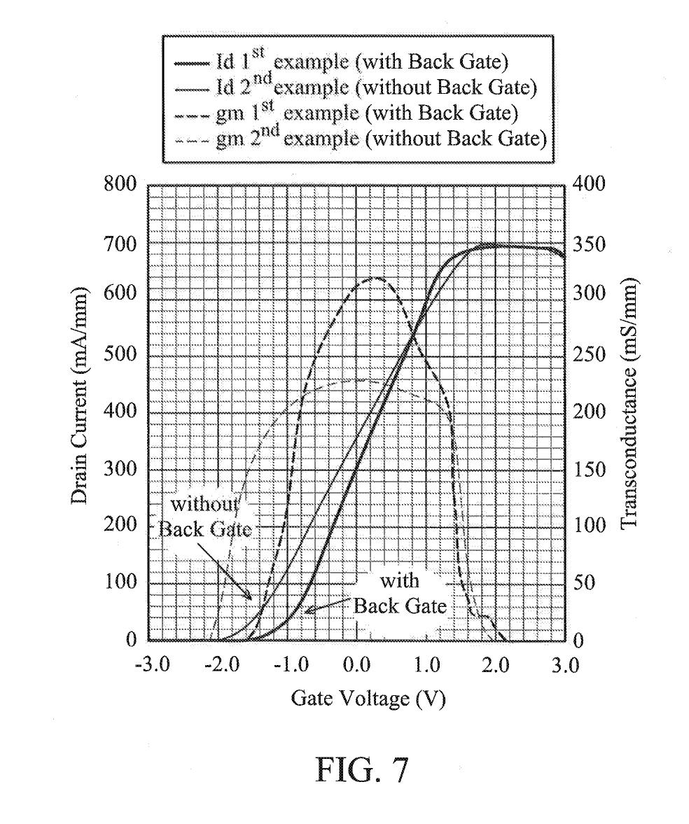

FIG. 6A shows a nitride based semiconductor device of a first example of the invention, wherein gate electrodes 122 and back gate electrodes 116 at two sides are connected together. FIG. 6B shows a nitride based semiconductor device of a second example of the invention, wherein no 2DHG is formed. The semiconductor devices of the two examples were tested and the results are shown in the Table 1 and FIG. 7, wherein FIG. 7 shows a curve diagram of the two examples with drain current and transconductance as a function of gate voltage. As shown in Table 1 and FIG. 7, the nitride based semiconductor device of the example 1 has larger transconductance, i.e. best gate controllability, and large enough drain current.

TABLE 1

| | Id, max | gm (ms/mm) |
|---|---|---|
| 1^{st} example (with back gate) | 695.8 | 227.3 |
| 2^{nd} example (without back gate) | 689.3 | 319.9 |

According to the descriptions and tests above, the nitride based semiconductor device of the invention has the advantages as follows. The nitride based semiconductor device has both a gate electrode and a back gate electrode in accordance with the 2DHG layer to control one 2DEG channel layer, such that gate controllability is improved and threshold voltage is reduced.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A nitride-based semiconductor device comprising:
a substrate;
an active region comprising a plurality of nitride-based semiconductor layers disposed on the substrate, wherein a two-dimensional electron gas (2DEG) channel and a two-dimensional hole gas (2DHG) under the 2DEG channel are formed within the plurality of nitride-based semiconductor layers;
a gate electrode disposed on the top of the active region; and
an interconnection structure electrically connected with the gate electrode and the 2DHG.

2. The nitride-based semiconductor device as claimed in claim 1, wherein the active region comprises:
a first barrier layer disposed on the substrate;
a channel layer disposed on the first barrier layer; and
a second barrier layer disposed on the channel layer;
wherein the 2DHG is formed adjacent to a first interface between the first barrier and the channel layer, and the 2DEG channel is formed adjacent to a second interface between the second barrier and the channel layer.

3. The nitride-based semiconductor device as claimed in claim 1, wherein the first barrier layer comprises AlₓGa₁₋ₓN, and wherein x is 15%˜35%.

4. The nitride-based semiconductor device as claimed in claim 1, wherein the first barrier layer has a thickness in a range of 10˜40 nm.

5. The nitride-based semiconductor device as claimed in claim 1, wherein the channel layer comprises Al_{y}Ga_{1-y}N, and wherein y is 0%˜10%.

6. The nitride-based semiconductor device as claimed in claim 1, wherein the channel layer has a thickness in a range of 20˜50 nm.

7. The nitride-based semiconductor device as claimed in claim 1, wherein the second barrier layer comprises AlₓGa₁₋ₓN, and wherein z is 15%˜35%.

8. The nitride-based semiconductor device as claimed in claim 1, wherein the second barrier layer has a thickness in a range of 10˜40 nm.

9. The nitride-based semiconductor device as claimed in claim 2, wherein the channel layer has a bandgap smaller than the first barrier layer and the second barrier layer.

10. The nitride-based semiconductor device as claimed in claim 1, further comprising a buffer layer disposed between the substrate and the active region.

11. The nitride-based semiconductor device as claimed in claim 10, further comprising a source electrode and a drain electrode disposed on the active region.

12. A nitride-based semiconductor device comprising, comprising:
a substrate;
an active region comprising a plurality of nitride-based semiconductor layers disposed on the substrate, wherein a two-dimensional electron gas (2DEG) channel and a two-dimensional hole gas (2DHG)—under the 2DEG channel are formed within the plurality of nitride-based semiconductor layers;
a first gate electrode disposed on the top of the active region; and
a second gate electrode electrically connected to the 2DHG,
wherein the first gate electrode controls the 2DEG channel and the second gate electrode controls the 2DEG channel via the 2DHG.

13. The nitride-based semiconductor device as claimed in claim 12, wherein the first gate electrode and the second gate electrode are connected with each other.

14. The nitride-based semiconductor device as claimed in claim 13, further comprising an interconnection structure electrically connected with the first gate electrode and the second gate electrode.

15. The nitride-based semiconductor device as claimed in claim 12, wherein the first gate electrode and the second gate electrode are operated independently.

16. The nitride-based semiconductor device as claimed in claim 12, wherein the active region comprises:
a first barrier layer disposed on the substrate;
a channel layer disposed on the first barrier layer; and
a second harrier layer disposed on the channel layer,
wherein the 2DHG is formed adjacent to a first interface between the first barrier and the channel layer, and the 2DEG channel is formed adjacent to a second interface between the second barrier and the channel layer.

17. The nitride-based semiconductor device as claimed in claim 16, wherein the first barrier layer comprises AlₓGa₁₋ₓN, and wherein x is 15%˜35% and has a thickness in a range of 10˜40 nm.

18. The nitride-based semiconductor device as claimed in claim 16, wherein the channel layer comprises Al_{y}Ga_{1-y}N, and wherein y is 0%˜10% and has a thickness in a range of 20˜50 nm.

19. The nitride-based semiconductor device as claimed in claim 16, wherein the second harrier layer comprises Al_{z}Ga_{1-z}N, and wherein z is 15%˜35% and has a thickness in a range of 10˜40 nm.

20. A nitride-based power semiconductor device comprising:
a substrate; and
an active, region disposed on the substrate, the active region comprising a plurality of stacked nitride-based semiconductor layers with different bandgaps;
wherein a two-dimensional electron gas (2DEG) channel and a two-dimensional hole gas (2DHG) channel under the 2DEG channel are formed within the active region.
